(19) United States
(12) Patent Application Publication
(10) Pub. No.: US 2017/0247608 A1
(43) Pub. Date: Aug. 31, 2017

(54) PROPPANT OF AN ELECTRICALLY-CONDUCTIVE NANO MATERIAL

(71) Applicant: Halliburton Energy Services, Inc., Houston, TX (US)

(72) Inventors: Neelam Raysoni, Pune (IN); Rajender Salla, Pune (IN)

(21) Appl. No.: 15/515,970

(22) PCT Filed: Oct. 30, 2014
(86) PCT No.: PCT/US2014/063194

§ 371 Date: Mar. 30, 2017

(51) Int. Cl. C09K 8/80; E21B 43/267; E21B 43/25; E21B 43/26; C23C 14/06; C23C 14/22

(52) U.S. Cl. CPC C09K 8/805; C23C 14/06; C23C 14/22; E21B 43/25; E21B 43/26; E21B 43/267; C01B 31/0206; C01B 31/0438

(57) ABSTRACT

A system for mapping a fracture comprising: a fracture located within a subterranean formation; a proppant pack located within the fracture, wherein at least a portion of the proppant are coated with a curable resin system comprising a curable resin and an electrically-conductive, nano-sized material, and wherein the coated proppant is electrically conductive; a transmitter that sends an electrical signal into the proppant pack; and a receiver that receives the electrical signal from the proppant pack. A method of mapping at least a portion of a fracture comprising: introducing proppant into the fracture; coating at least a portion of the proppant with a curable resin system, wherein the curable resin system comprises: a curable resin; and an electrically-conductive, nano-sized material, wherein at least the portion of the proppant becomes electrically-conductive after the step of coating; and using the electrically-conductive proppant to map at least the portion of the fracture.

### TECHNICAL FIELD

Hydraulic fracturing operations can be used to stimulate production of a reservoir fluid. Proppant is commonly placed within the fractures to prop the fracture open. Electrically-conductive proppant can be used to map the geometry of the fractures.

### BRIEF DESCRIPTION OF THE FIGURES

The features and advantages of certain embodiments will be more readily appreciated when considered in conjunction with the accompanying figures. The figures are not to be construed as limiting any of the preferred embodiments.

FIG. 1 is a diagram illustrating a fracturing system according to certain embodiments.

FIG. 2 is a diagram illustrating a well system in which a fracturing operation can be performed.

### DETAILED DESCRIPTION

Oil and gas hydrocarbons are naturally occurring in some subterranean formations. In the oil and gas industry, a subterranean formation containing oil or gas is referred to as a reservoir. A reservoir may be located under land or off shore. Reservoirs are typically located in the range of a few hundred feet (shallow reservoirs) to a few tens of thousands of feet (ultra-deep reservoirs). In order to produce oil or gas, a wellbore is drilled into a reservoir or adjacent to a reservoir. The oil, gas, or water produced from the wellbore is called a reservoir fluid.

As used herein, a “fluid” is a substance having a continuous phase that tends to flow and to conform to the outline of its container when the substance is tested at a temperature of 71° F. (22° C.) and a pressure of 1 atmosphere “atm” (0.1 megapascals “MPa”). A fluid can be a liquid or gas. A homogenous fluid has only one phase; whereas a heterogeneous fluid has more than one distinct phase. A heterogeneous fluid can be: a slurry, which includes a continuous liquid phase and undissolved solid particles as the dispersed phase; an emulsion, which includes a continuous liquid phase and at least one dispersed phase of immiscible liquid droplets; a foam, which includes a continuous liquid phase and a gas as the dispersed phase; or a mist, which includes a continuous gas phase and liquid droplets as the dispersed phase. As used herein, a “base fluid” is the liquid that is in the greatest concentration and will be the solvent of a solution or the continuous liquid phase of a heterogeneous fluid. The base fluid can contain dissolved or undissolved substances.

A well can include, without limitation, an oil, gas, or water production well, or an injection well. As used herein, a “well” includes at least one wellbore. A wellbore can include vertical, inclined, and horizontal portions, and it can be straight, curved, or branched. As used herein, the term “wellbore” includes any cased, and any uncased, open-hole portion of the wellbore. A near-wellbore region is the subterranean material and rock of the subterranean formation surrounding the wellbore. As used herein, a “well” also includes the near-wellbore region. The near-wellbore region is generally considered the region within approximately 100 feet radially of the wellbore. As used herein, “into a well” means and includes into any portion of the well, including into the wellbore or into the near-wellbore region via the wellbore. As used herein, “into a subterranean formation” means and includes into any portion of a subterranean formation including, into a well, wellbore, or the near-wellbore region via the wellbore.

A portion of a wellbore may be an open hole or cased hole. In an open-hole wellbore portion, a tubing string may be placed into the wellbore. The tubing string allows fluids to be introduced into or flowed from a remote portion of the wellbore. In a cased-hole wellbore portion, a casing is placed into the wellbore that can also contain a tubing string. A wellbore can contain an annulus. Examples of an annulus include, but are not limited to: the space between the wellbore and the outside of a tubing string in an open-hole wellbore; the space between the wellbore and the outside of a casing in a cased-hole wellbore; and the space between the inside of a casing and the outside of a tubing string in a cased-hole wellbore.

There are primary and remedial wellbore operations in which it is desirable to consolidate particles together. Examples of particles that are commonly consolidated together to form a consolidated pack of particles are proppant, gravel, and formation particles, such as sand and fines. Proppant is commonly used in conjunction with hydraulic fracturing operations (fracing operations). A fracturing fluid is pumped using a frac pump at a sufficiently high flow rate and high pressure into the wellbore and into the subterranean formation to create or enhance a fracture in the subterranean formation. Creating a fracture means making a new fracture in the formation. Enhancing a fracture means enlarging a pre-existing fracture in the formation. As used herein, the term “fracture” means the creation or enhancement of a natural fracture using a fracturing fluid, and can be referred to as “man-made.” To fracture a subterranean formation typically requires hundreds of thousands of gallons of fracturing fluid. Further, it is often desirable to fracture at more than one downhole location. Therefore, the base fluid of a fracturing fluid is usually water or water-based for various reasons, including the ready availability of water and the relatively low cost of water compared to other liquids.

The newly-created or enhanced fracture will tend to close together after pumping of the fracturing fluid has stopped due to the weight of the subterranean formation. To prevent the fracture from closing, a material must be placed in the fracture to keep the fracture propped open. A material used for this purpose is often referred to as a “proppant.” The proppant is in the form of solid particles, which can be suspended in the fracturing fluid, carried down hole, and deposited in the fracture as a “proppant pack.” The proppant pack generally props the fracture in an open position while allowing fluid flow through the permeability of the pack.

Proppant materials generally include silicon dioxide, walnut shells, sintered bauxite, glass, plastics, ceramic materials, and any combination thereof in any proportion. The proppant is an appropriate size to prop open the fracture and allow fluid to flow through the proppant pack, that is, in between and around the proppant making up the pack. Appropriate sizes of particulate for use as a proppant are typically in the range from about 8 to about 100 U.S. Standard Mesh. A typical proppant is sand-sized, which geologically is defined as having a largest dimension ranging from 0.0625 millimeters up to 3 millimeters.

The proppant should be sufficiently strong, that is, has a sufficient compressive or crush resistance, to prop the fracture open without being deformed or crushed by the closure stress of the fracture from the subterranean formation. Pressures from the subterranean formation on the proppant located in the fractures can be as high as 10,000 to generally 15,000 or more pounds force per square inch (psi). If a proppant material crushes close stress, then the fracture will close and no longer function to provide a less restrictive fluid flow path for production of reservoir fluids.

Once the proppant is placed within the fractures, if the proppant is not held in place, then the proppant can flow towards the wellhead during production. This undesirable migration can cause damage to wellbore equipment and potentially a loss of integrity, for example to the fracture or wellbore. Therefore, it is often desirable to coat the proppant with a resin to form a consolidated pack. The resin should have an affinity for the proppant and should coat the proppant. The resin can be a tacky resin that acts as a glue to bind the proppant of the pack together. The resin can also be part of a consolidation system that comprises a curable resin and a curing agent. The curing agent causes the curable resin to cure and become hard and solid via a chemical reaction, wherein heat can increase the reaction rate. After the resin cures, the proppant of the pack are consolidated. The proppant of a consolidated pack can then remain in the desired location either temporarily or permanently. If the proppant pack consolidates into a hard pack, then the resin can be said to aid in increasing the crush resistance of the proppant under a given overburden stress. The amount of resin used depends on the desired strength of the proppant at that particular overburden stresses. However, if the resin system is only tacky in nature and simply holds the proppants and fines in place, it would not aid in increasing the crush resistance of the proppant. In this instance, the tacky resin would just help keep the fines and proppant from moving into the pore spaces and hence helps in maintaining the conductivity for some time period.

It is often desirable to map the fracture geometry of the proppant pack located within a fracture. Electro-conductive proppant compositions can be used to determine, among other things, proppant pack characteristics such as dimensions, orientation, and conductivity. Several techniques are currently being used like resin treating the proppant for maintaining strength and conductivity of the proppant pack. In order to map the fracture and proppant placement, radioactive tracers can be used. Fractures can also be mapped using dipole sonic logs; however, significant differences in shear are needed in order to map the fractures. However, these processes cannot guarantee accurate mapping of fractures.

Therefore, there is a need and an ongoing industry-wide concern for being able to accurately map the location of the proppant pack and fracture geometry. It has been discovered that a curable resin system including nanoparticles of graphene and derivatives can be used to provide electrically-conductive proppant. The electrically-conductive proppant can be placed into fractures to create a proppant pack and allow for accurate mapping of the fracture and proppant placement. It is also well known that nano-sized materials can be used instead of larger sized particles due to the oftentimes unique properties that nano-sized materials possess. As used herein, a “nano-sized material” is a material having a largest cross-sectional surface area less than 0.1 micrometers (μm).

According to certain embodiments, a method of mapping at least a portion of a fracture comprises: introducing proppant into the fracture; coating at least a portion of the proppant with a curable resin system, wherein the curable resin system comprises: (A) a curable resin; and (B) an electrically-conductive, nano-sized material, wherein at least the portion of the proppant becomes electrically-conductive after the step of coating; and using the electrically-conductive proppant to map at least the portion of the fracture. The coating of resin and nano-sized material onto proppant can be both—on the fly as well as pre-cured/pre-treatment methods.

According to certain other embodiments, a system for mapping a fracture comprises: (A) one or more fractures located within a subterranean formation; (B) a proppant pack located within the one or more fractures, wherein at least a portion of the proppant of the proppant pack are coated with a curable resin system comprising a curable resin and an electrically-conductive, nano-sized material, and wherein the coated proppant is electrically conductive; (C) a transmitter that sends an electrical signal into the proppant pack; and (D) a receiver that receives the electrical signal from the proppant pack.

It is to be understood that the discussion of preferred embodiments regarding the proppant, the curable resin system, or the fracture are intended to apply to the method, system, and composition embodiments.

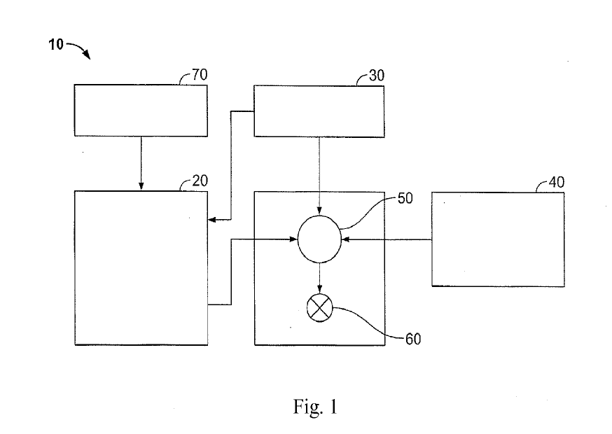

The fracturing system 10 of FIG. 1 can include a fracturing fluid producing apparatus 20, a fluid source 30, a proppant source 40, and a pump and blender system 50 and resides at the surface at a well site where a well 60 is located. In certain embodiments, the fracturing fluid producing apparatus 20 combines a gel precursor with fluid (e.g., liquid or substantially liquid) from fluid source 30, to produce a hydrated fracturing fluid that is used to fracture the formation. The hydrated fracturing fluid can be a fluid for ready use in a fracture stimulation treatment of the well 60 or a concentrate to which additional fluid is added prior to use in a fracture stimulation of the well 60. In other instances, the fracturing fluid producing apparatus 20 can be omitted and the fracturing fluid sourced directly from the fluid source 30.

The proppant source 40 can include a proppant for combining with the fracturing fluid. The system may also include additive source 70 that provides one or more additives (e.g., gelling agents, weighting agents, and/or other optional additives) to alter the properties of the fracturing fluid. This source can also have a hopper for on the fly coating of the proppant with the coating and nano material, or this source can be used to introduce pre-treated or pre-cured resin coated proppant into a treatment fluid.

The pump and blender system 50 can receive the fracturing fluid and combine it with other components, including proppant from the proppant source 40 and/or additional fluid from the additives 70. The resulting mixture may be pumped down the well 60 under a pressure sufficient to create or enhance one or more fractures in a subterranean zone, for example, to stimulate production of fluids from the zone. The fracturing fluid producing apparatus 20, fluid source 30, and/or proppant source 40 can each be equipped with one or more metering devices (not shown) to control the flow of fluids, proppant, and/or other compositions to the pumping and blender system 50. Such metering devices can facilitate the pumping. The blender system 50 can source from one, some, or all of the different sources at a given time, and can facilitate the preparation of fracturing fluids using continuous mixing or “on-the-fly” methods. Thus, for example, the pumping and blender system 50 can provide just fracturing fluid into the well at times, just proppant at other times, and combinations of those components at yet other times.

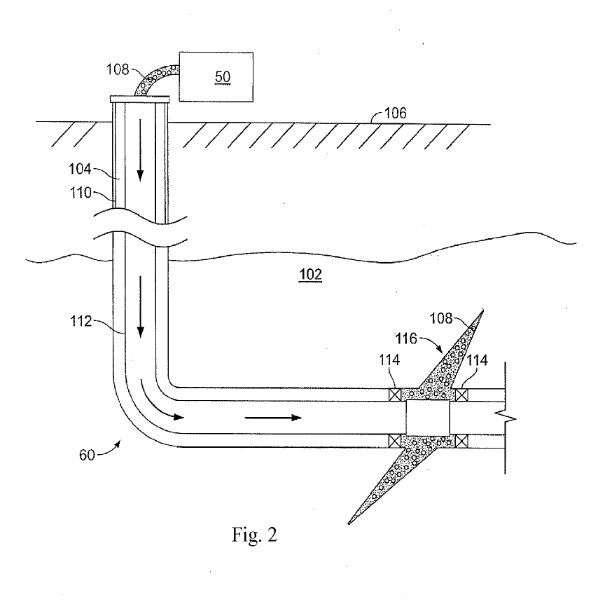

The step of introducing can comprise pumping the fracturing fluid into the subterranean formation. FIG. 2 shows the well 60 during a fracturing operation in a portion of a subterranean formation 102. The subterranean formation can be penetrated by a well. The well can be, without limitation, an oil, gas, or water production well, an injection well, or a geothermal well. The well can also be an offshore well. The step of introducing can also include introducing the fracturing fluid into the well. The well includes a wellbore 104. The wellbore 104 extends from the surface 106, and the fracturing fluid 108 is introduced into a portion of the subterranean formation 102. The wellbore 104 can include a casing 110 that is cemented or otherwise secured to the wellbore wall. The wellbore 104 can be uncased or include uncased sections. Perforations can be formed in the casing 110 to allow fracturing fluids and/or other materials to flow into the subterranean formation 102. In cased wells, perforations can be formed using shaped charges, a perforating gun, hydro-jetting and/or other tools.

The well is shown with a work string 112. The pump and blender system 50 can be coupled to the work string 112 to pump the fracturing fluid 108 into the wellbore 104. The work string 112 can include coiled tubing, jointed pipe, and/or other structures that allow fluid to flow into the wellbore 104. The work string 112 can include flow control devices, bypass valves, ports, and or other tools or well devices that control a flow of fluid from the interior of the work string 112 into the subterranean formation 102. For example, the work string 112 can include ports (not shown) located adjacent to the wellbore wall to communicate the fracturing fluid 108 directly into the subterranean formation 102, and/or the work string 112 can include ports that are spaced apart from the wellbore wall to communicate the fracturing fluid 108 into an annulus that is located between the outside of the work string 112 and the wall of the wellbore.

The well system can include one or more sets of packers 114 that create one or more wellbore intervals. The methods also include creating or enhancing one or more fractures within the subterranean formation using the fracturing fluid. When the fracturing fluid 108 is introduced into wellbore 104 (e.g., in FIG. 2, the wellbore interval located between the packers 114) at a sufficient hydraulic pressure, one or more fractures 116 may be created in the subterranean formation 102. The proppant particulates in the fracturing fluid 108 can enter the fractures 116 where they may remain after the fracturing fluid flows out of the wellbore. The proppant can be placed into the one or more fractures during the step of introducing. The proppant can form a proppant pack within the one or more fractures.

The proppant can be selected from the group consisting of nut shells, sand, ceramics, natural sand, quartz sand, particulate garnet, metal particulates, glass, nylon pellets, bauxite and other ores, polymeric materials, and combinations thereof in any proportion. The proppant can have a particle size range from 4 to 100 U.S. mesh, or from 10 to 70 U.S. mesh. The proppant particles themselves may be at least somewhat electrically conductive (as in the case of bauxite-based particles) or very conductive (as in the case of copper-based particles). The proppant particles can be substantially spherical in shape, fibrous materials, polygonal shaped (such as cubic), irregular shapes, and any combination thereof.

At least a portion of the proppant is coated with a curable resin system. According to certain embodiments, only chosen portions of the proppant making up a proppant pack can be coated with the curable resin system. Substantially all of the proppant making up the proppant pack are coated with the curable resin system. The amount of proppant that is coated can also be in the range of about 20% to about 100%, about 30% to about 90%, or about 50% to about 85%. According to certain embodiments, the curable resin is in a concentration of about 0.5% to about 10% or about 1% to about 3% volume by weight of the proppant. According to certain embodiments, the concentration of the curable resin is selected such that the proppant has a desired conductivity and strength, depending on the type of resin used.

The curable resin system includes a curable resin. The resin should have an affinity for the proppant and should coat the proppant. The resin can be hydrophobic. The resin can be a tacky resin that acts as a glue to bind the proppant of the pack together. The resin can also be part of a consolidation system that comprises the curable resin and a curing agent. The curing agent causes the curable resin to cure and become hard and solid via a chemical reaction, wherein heat can increase the reaction rate. After the resin cures, the proppant of the pack are consolidated. The proppant of a consolidated pack can then remain in the desired location either temporarily or permanently. The curable resin can be selected from the group consisting of two-component epoxy-based resins, novolac resins, polyepoxide resins, phenol-aldehyde resins, urea-aldehyde resins, urethane resins, phenolic resins, furan resins, furan/furfuryl alcohol resins, phenolic/latex resins, phenol formaldehyde resins, polyester resins and hybrids and copolymers thereof, polyurethane resins and hybrids and copolymers thereof, acrylate resins, and combinations thereof.

The curable resin system can also include a curing agent for the curable resin. Preferably, the curable resin does not cure until the proppant pack has been formed. The curable resin can cure when in contact with a suitable curing agent. Examples of suitable curing agents include, but are not limited to, amines, amides, acids, anhydrides, phenols, thiols, and combinations thereof.

The curable resin system also includes an electrically-conductive, nano-sized material. The material can be solid particles. The material can be graphene and derivatives of graphene. Suitable electrically-conductive, nano-sized materials include, but are not limited to, as-produced graphene, single-layer graphene, multi-layer graphene, graphene platelets, graphene sheets, graphene nano ribbons, carbon nanotubes, graphene oxide, reduced graphene, functionalized graphene, any hybrid variant thereof, and any combination thereof. Unless otherwise indicated, the generic term “graphene” will be used synonymously herein with the term “graphene materials” to refer to any of these specific forms or types of graphene. Hybrid variants of the foregoing graphene materials are also possible. As non-limiting examples, hybrid variants can include the following: multi-layer graphene that been reduced, multi-layer graphene that has been functionalized, multi-layer graphene nano ribbons, single-layer graphene nano ribbons, graphene nano ribbons that have been reduced, and graphene nano ribbons that have been functionalized.

The electrically-conductive, nano-sized material can be included with the curable resin and optionally the curing agent and then coated onto the proppant. Accordingly, the material and the curable resin (and optionally the curing agent) can be mixed together via a suitable mixing apparatus. The mixture can then be coated onto at least the portion of the proppant according to methods known to those skilled in the art. Alternatively, the portion of the proppant can be coated with the curable resin (and optionally the curing agent) and then the electrically-conductive, nano-sized material can be added to the coated proppant to form the curable resin system. Additionally, the curing agent for the curable resin can be introduced into the fracture to come in contact with the coated proppant after the proppant has been introduced into the fracture. In this manner, the curing agent can cause the curable resin to cure and consolidate the proppant of the proppant pack together.

The electrically-conductive, nano-sized material can be in a concentration in the range of about 0.01% to about 2% or about 0.1% to about 1% weight by weight of the curable resin. The electrically-conductive, nano-sized material can also be in an amount sufficient to obtain a desired degree of conductivity of the coated proppant. In this manner the fracture can be mapped using the electrically-conductive proppant.

The proppant that is coated with the curable resin system becomes electrically conductive. The methods include using the electrically-conductive proppant to map at least the portion of the fracture. According to certain embodiments, the entire fracture is mapped. Moreover, there can be more than one fracture that is mapped using the electrically-conductive proppant. The fracture can be mapped using a variety of mapping techniques, including using SP logs, resistivity logs, seismic logs, and sonic logs. A change in resistivity of the electrically-conductive proppant in contrast to the resistivity of the surrounding formation can be used to map the fracture and confirm that the fracture job was executed as planned. SP and sonic logs can be used to measure electrical potentials of the electrically-conductive proppant and can measure the fracture width and height. Besides the above-mentioned techniques of using logging tools, surface seismic measurements can also be used to detect fracture orientation.

One or more transmitters can be used to send an electrical signal into an electrically-conductive proppant pack and receivers can be used to collect information from the electrically-conductive proppant pack. According to certain embodiments, the signal comprises an electric current or an electromagnetic field. The electric or electromagnetic signal from the transmitter can be conducted along, and reflected back from the electrically-conductive proppant to the receiver and can be used to determine, inter alia, the dimensions and geometry (i.e., height, width, length, and orientation) of the fracture. According to certain embodiments, an electric current can be used to determine the electrical impedance within the electrically-conductive proppant to quantitatively measure the proppant conductivity or the distribution of proppant conductivity through the fracture.

At least one receiver can be placed in the wellbore of the subterranean formation. For example, a single receiver can be placed in the wellbore at the fracture initiation point. According to another example, multiple receivers can be placed in the wellbore in the region of the fracture to determine the spatial distribution of the electrically-conductive proppant in the fracture (e.g., to determine the fracture height and width). The receiver can also be located at the wellhead of the wellbore. The receiver can be directly or operatively connected to a computer for displaying the information received from the transmitter. One or more repeaters can also be included to relay the information from the transmitter to the receiver.

Optical responses of graphene and its derivatives can be tuned electrically. This flexibility in tuning can be useful to ensure compatibility between different types of signals being received and transmitted between the electrically-conductive proppant and logging tools. This helps to enhance fracture network mapping.

The proppant can be introduced into the fracture in a treatment fluid, such as a fracturing fluid. The treatment fluid can include the coated proppant, un-coated proppant, and a base fluid. As used herein, the term “base fluid” means the liquid that is in the greatest concentration and is the solvent of a solution or the continuous phase of a heterogeneous fluid. The base fluid can be several hundreds to thousands of gallons for the treatment fluid. The base fluid can include water. The water can be selected from the group consisting of fresh water, brackish water, sea water, brine, produced water—as it is or processed, and any combination thereof in any proportion. The treatment fluid can also include water-miscible liquids, hydrocarbon liquids, and gases.

The treatment fluid can also contain various other additives. Any of these additives may be present in a coating of the curable resin system. The other additives can include, for example, silica scale control additives, surfactants, gel stabilizers, anti-oxidants, polymer degradation prevention additives, relative permeability modifiers, scale inhibitors, corrosion inhibitors, foaming agents, defoaming agents, antifoaming agents, emulsifying agents, de-emulsifying agents, iron control agents, particulate diverters, salts, acids, fluid loss control additives, gas, catalysts, clay control agents, dispersants, flocculants, scavengers (e.g., H₂S scavengers, CO₂ scavengers or O₂ scavengers), gelling agents, lubricants, breakers, friction reducers, bridging agents, viscosifiers, weighting agents, solubilizers, pH control agents (e.g., buffers), hydrate inhibitors, consolidating agents, bactericides, catalysts, clay stabilizers, breakers, delayed release breakers, and the like.

The exemplary fluids and additives disclosed herein may directly or indirectly affect one or more components or pieces of equipment associated with the preparation, delivery, recapture, recycling, reuse, and/or disposal of the disclosed fluids and additives. For example, the disclosed fluids and additives may directly or indirectly affect one or more mixers, related mixing equipment, mud pits, storage facilities or units, fluid separators, heat exchangers, sensors, gauges, pumps, compressors, and the like used generate, store, monitor, regulate, and/or recondition the exemplary fluids and additives. The disclosed fluids and additives may also directly or indirectly affect any transport or delivery equipment used to convey the fluids and additives to a well site or downhole such as, for example, any transport vessels, conduits, pipelines, trucks, tubulars, and/or pipes used to fluidically move the fluids and additives from one location to another, any pumps, compressors, or motors (e.g., topside or downhole) used to drive the fluids and additives into motion, any valves or related joints used to regulate the pressure or flow rate of the fluids, and any sensors (i.e., pressure and temperature), gauges, and/or combinations thereof, and the like. The disclosed fluids and additives may also directly or indirectly affect the various downhole equipment and tools that may come into contact with the fluids and additives such as, but not limited to, drill string, coiled tubing, drill pipe, drill collars, mud motors, downhole motors and/or pumps, floats, MWD/LWD tools and related telemetry equipment, drill bits (including roller cone, PDC, natural diamond, hole openers, reamers, and coring bits), sensors or distributed sensors, downhole heat exchangers, valves and corresponding actuation devices, tool seals, packers and other wellbore isolation devices or components, and the like.

Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is, therefore, evident that the particular illustrative embodiments disclosed above may be altered or modified and all such variations are considered within the scope and spirit of the present invention.

As used herein, the words “comprise,” “have,” “include,” and all grammatical variations thereof are each intended to have an open, non-limiting meaning that does not exclude additional elements or steps. While compositions and methods are described in terms of “comprising,” “containing,” or “including” various components or steps, the compositions and methods also can “consist essentially of” or “consist of” the various components and steps. Whenever a numerical range with a lower limit and an upper limit is disclosed, any number and any included range falling within the range is specifically disclosed. In particular, every range of values (of the form, “from about a to about b,” or, equivalently, “from approximately a to b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces. If there is any conflict in the usages of a word or term in this specification and one or more patent(s) or other documents that may be incorporated herein by reference, the definitions that are consistent with this specification should be adopted.

What is claimed is:

1. A method of mapping at least a portion of a fracture comprising:
introducing proppant into the fracture;
coating at least a portion of the proppant with a curable resin system, wherein the curable resin system comprises:
(A) a curable resin; and
(B) an electrically-conductive, nano-sized material, wherein at least the portion of the proppant becomes electrically-conductive after the step of coating; and
using the electrically-conductive proppant to map at least the portion of the fracture.

2. The method according to claim 1, wherein the curable resin is in a concentration of about 0.5% to about 10% volume by weight of the proppant.

3. The method according to claim 1, wherein the curable resin is selected from the group consisting of two-component epoxy-based resins, novolac resins, polyepoxide resins, phenol-aldehyde resins, urea-aldehyde resins, urethane resins, phenolic resins, furan resins, furan/furfuryl alcohol resins, phenolic/latex resins, phenol formaldehyde resins, polyester resins and hybrids and copolymers thereof, polyurethane resins and hybrids and copolymers thereof, acrylate resins, and combinations thereof.

4. The method according to claim 1, wherein the curable resin cures when in contact with a curing agent.

5. The method according to claim 4, wherein the curing agent is selected from the group consisting of amines, amides, acids, anhydrides, phenols, thiols, and combinations thereof.

6. The method according to claim 5, wherein the curable resin system further comprises the curing agent for the curable resin.

7. The method according to claim 5, wherein the curing agent for the curable resin is introduced into the fracture after the step of introducing the proppant.

8. The method according to claim 1, wherein the electrically-conductive, nano-sized material is graphene and derivatives of graphene.

9. The method according to claim 8, wherein the electrically-conductive, nano-sized materials is selected from the group consisting of as-produced graphene, single-layer graphene, multi-layer graphene, graphene platelets, graphene sheets, graphene nano ribbons, carbon nanotubes, graphene oxide, reduced graphene, functionalized graphene, any hybrid variant thereof, and combinations thereof.

10. The method according to claim 1, wherein the electrically-conductive, nano-sized material is in a concentration in the range of about 0.01% to about 2% weight by weight of the curable resin.

11. The method according to claim 1, wherein the electrically-conductive, nano-sized material is mixed together with at least the curable resin to form the curable resin system with a mixing apparatus prior to coating at least the portion of the proppant.

12. The method according to claim 1, wherein at least the portion of the proppant is coated with at least the curable resin and then the electrically-conductive, nano-sized material is added to the coated proppant to form the curable resin system.

13. The method according to claim 1, wherein at least the portion of the proppant is coated prior to the step of introducing the proppant into the fracture as a pre-treatment.

14. The method according to claim 1, wherein at least the portion of the proppant is coated on-the-fly during the step of introducing the proppant into the fracture.

15. The method according to claim 1, wherein the proppant forms a proppant pack within the fracture.

16. The method according to claim 15, wherein a transmitter sends an electrical signal into the electrically-conductive proppant pack and a receiver collects information from the electrically-conductive proppant pack.

17. The method according to claim 16, wherein the mapping determines at least one of the following: the dimensions of the fracture; the geometry of the fracture; or the electrical impedance within the electrically-conductive proppant to quantitatively measure the proppant conductivity or the distribution of proppant conductivity through the fracture.

18. The method according to claim 1, wherein the proppant is introduced into the fracture as part of a treatment fluid comprising a base fluid.

19. The method according to claim 18, wherein the base fluid and the proppant are introduced into the fracture using one or more pumps.

20. A system for mapping a fracture comprising:
(A) one or more fractures located within a subterranean formation;
(B) a proppant pack located within the one or more fractures,
wherein at least a portion of the proppant of the proppant pack are coated with a curable resin system comprising a curable resin and an electrically-conductive, nano-sized material, and wherein the coated proppant is electrically conductive;
(C) a transmitter that sends an electrical signal into the proppant pack; and
(D) a receiver that receives the electrical signal from the proppant pack.

21. A proppant pack comprising:
proppant coated with a curable resin system comprising a curable resin and an electrically-conductive, nano-sized material.
